(19) United States
(12) Patent Application Publication
(10) Pub. No.: US 2022/0223770 A1
(43) Pub. Date: Jul. 14, 2022

(54) OPTICAL DISPLAY DEVICE WITH AMBIENT CONTRAST ENHANCEMENT COVER PLATE

(71) Applicants: CORNING PRECISION MATERIALS CO., LTD., ASAN (KR); CORNING INCORPORATED, CORNING, NY (US)

(72) Inventors: Sang-cheol Jung, Seongnam-si (KR); Dae youn Kim, Asan-si (KR); Goo Soo Lee, Seoul (KR); Kyung-jin Lee, Cheonan-si (KR); Dong Keun Shin, Hwasung-si (KR); Hong Yoon, Asan-si (KR)

(21) Appl. No.: 17/611,832

(22) PCT Filed: May 15, 2020
(86) PCT No.: PCT/US2020/033019

§ 371 Date: Nov. 16, 2021

Related U.S. Application Data
(60) Provisional application No. 63/021,167, filed on May 7, 2020.
(60) Provisional application No. 62/930,861, filed on Nov. 5, 2019.
(60) Provisional application No. 62/849,497, filed on May 17, 2019.

(51) Int. Cl. H01L 33/58; H01L 25/075

(52) U.S. Cl. CPC H01L 33/58; H01L 2933/0058; H01L 25/0753

(57) ABSTRACT

An optical display device having a backplane substrate and a cover plate adjacent to and spaced apart from the backplane substrate is provided. The backplane substrate can include a plurality of electroluminescent elements disposed thereon and the cover plate can include a plurality of light absorbing wedge-shaped features arranged in rows thereon.

### CROSS-REFERENCE TO RELATED APPLICATIONS

This application claims the benefit of priority of U.S. Provisional Application Ser. No. 63/021,167 filed on May 7, 2020 which claims the benefit of priority of U.S. Provisional Application Ser. No. 62/930,861 filed on Nov. 5, 2019 and 62/849,497 filed on May 17, 2019 the contents of which are relied upon and incorporated herein by reference in their entities as if fully set forth below.

### FIELD

The present disclosure relates to an optical display device, and more particularly an optical display device including a cover plate configured to improve contrast of a displayed image in the presence of ambient light.

### BACKGROUND

Ambient light contrast can be an issue for self-emissive electro-luminescent displays like organic light emitting diode (OLED) and micro-light emitting diode (micro-LED) displays. Display panels with surfaces that include metallic electrodes and/or other reflective materials can reflect light from solar radiation or indoor lighting. For instance, OLED panels can have almost 80% surface reflectivity, primarily from metallic electrodes. Circular polarizers are often used as an optically functional film to reduce ambient light reflection and avoid a loss of display contrast ratio. However, such polarizing films can absorb up to 50% of incident light, thereby potentially reducing display brightness.

### SUMMARY

An optical display device comprising a cover plate adjacent to a backplane substrate is provided. The backplane substrate can include a plurality of electroluminescent elements deposited thereon. The cover plate can include a plurality of light absorbing wedge-shaped features arranged in rows.

Accordingly, an optical display device is disclosed comprising a backplane substrate comprising a plurality of electroluminescent elements deposited in parallel rows thereon, each row of electroluminescent elements comprising an alignment axis, a cover plate adjacent to and spaced apart from the backplane substrate, the cover plate comprising a contrast enhancement layer comprising a base substrate and a filter layer disposed thereon, the filter layer comprising a first plurality of light absorbing wedge-shaped features arranged in parallel rows in a light-transmissive matrix material, each wedge-shaped feature comprising a longitudinal axis, and wherein the longitudinal axes are angularly offset from the alignment axes by an angle in a range from greater than zero to 10 degrees.

In some embodiments, the cover plate may further comprise a light absorbing layer disposed between the filter layer and the base substrate. A thickness of the light absorbing layer can be in a range from about 10 nm to about 1 μm.

A height H1 of the first plurality of wedge-shaped features can be in a range from about 10 μm to about 100 μm, for example in a range from about 50 μm to about 100 μm.

In some embodiments, the cover plate may further comprise a second plurality of wedge-shaped features with a second height H2 different than H1, the first plurality of wedge-shaped features and the second plurality of wedge-shaped features disposed in an alternating arrangement. H2 can be in a range from about 5 μm to about 80 μm. In some embodiments, H2 can be less than H1.

Each wedge-shaped feature of the first plurality of wedge-shaped features can comprise a first maximum cross-sectional width W1 and each wedge-shaped feature of the second plurality of wedge-shaped features comprises a second maximum cross-sectional width W2 different than W1.

W1 can be in a range from about 10 μm to about 100 μm. W2 can be in a range from greater than 10 μm to about 50 μm.

In some embodiments, H1/W1 can be equal to or greater than about 3, for example, in a range from about 3 to about 6.

In some embodiments, a pitch P1 of the first plurality of wedge-shaped features can be in a range from about 50 μm to about 200 μm.

In some embodiments, a pitch P1 of the first plurality of wedge-shaped features can be in a range from about 50 μm to about 200 μm, for example in a range from about 60 μm to about 150 μm, from about 60 μm to about 100 μm, or in a range from about 60 μm to about 90 μm, and a pitch P2 of the second plurality of wedge-shaped features can be equal to the pitch of the first plurality of wedge-shaped features. The first plurality of wedge-shaped features can be equally spaced from the first plurality of wedge-shaped features. That is, a wedge-shaped feature of the second plurality of wedge-shaped features is positioned mid-way between two adjacent wedge-shaped features of the first plurality of wedge-shaped features.

In embodiments, an angle between a base of each wedge-shaped feature of the first plurality of wedge-shaped features and an adjacent side-wall of each wedge-shaped feature of the first plurality of wedge-shaped features is in a range from about 70 degrees to less than 90 degrees.

In various embodiments, an extinction coefficient k of the filter layer can be in a range from about 0.01 to about 1, such as from about 0.05 to about 1.

In some embodiments, the cover plate can comprise an anti-reflection film.

In some embodiments, each wedge-shaped feature of the first plurality of wedge-shaped features can comprise a trapezoidal cross-sectional shape, the trapezoidal cross-sectional shape comprising a base edge arranged on the first surface of the cover substrate and an opposing top edge projecting toward the plurality of electroluminescent elements.

The optical display device may not, in some embodiments, include an electromagnetic shield layer or a near IR-shielding layer.

In some embodiments, each electroluminescent element in the plurality of electroluminescent elements comprises an LED.

In some embodiments, the backplane substrate and the cover plate can be spaced apart by a gap of about 1 mm to about 5 mm.

The optical display device according to various embodiments can exhibit a viewing angle is greater than 30 degrees.

In some embodiments, a refractive index of the first plurality of wedge-shaped features is n_{B} and refractive index of the matrix material is n_{F}, and Δn=n_{B}−n_{F} is in a range from about −0.3 to about 0, for example in a range from about −0.1 to about 0.

The optical display device can comprise an ambient light reflection less than about 5% at an incident angle equal to or greater than about 40°.

In some embodiments, the base substrate can comprise glass.

In some embodiments, an ambient contrast ratio of the display device can be equal to or greater than about 400 while a transmittance of the cover plate is greater than 66%.

In other embodiments, an ambient contrast ratio of the display device can be equal to or greater than about 500 while a transmittance of the cover plate is greater than 60%.

In still other embodiments, an optical display device is described comprising a backplane substrate comprising a plurality of electroluminescent elements deposited in parallel rows thereon, each row of electroluminescent elements comprising an alignment axis, a cover plate adjacent to and spaced apart from the backplane substrate, the cover plate comprising a contrast enhancement layer comprising a base substrate and a filter layer disposed thereon and a light absorbing layer disposed between the base substrate and the filter layer, the filter layer comprising a first plurality of light absorbing wedge-shaped features arranged in parallel rows in a light-transmissive matrix material, each wedge-shaped feature comprising a longitudinal axis, and wherein the longitudinal axes are angularly offset from the alignment axes by an angle in a range from greater than zero to 10 degrees.

In some embodiments, the optical display device may further comprise a second plurality of wedge-shaped features arranged in parallel rows in an alternating arrangement with the first plurality of wedge-shaped features, wherein a height of the first plurality of wedge-shaped features is H1 and a height of the second plurality of wedge-shaped features is H2 different than H1.

In some embodiments, H2 can be less than H1.

In some embodiments, each wedge-shaped feature of the first plurality of wedge-shaped features can comprise a maximum cross-sectional width W1 and each wedge-shaped feature of the second plurality of wedge-shaped features can comprise a maximum cross-sectional width W2. An aspect ratio H1/W1 of the first plurality of wedge-shaped features can be different than an aspect ratio H2/W2 of the second plurality of wedge-shaped features.

In some embodiments, W2 can be less than W1.

In still other embodiments, an optical display device is disclosed, comprising a backplane substrate comprising a plurality of electroluminescent elements deposited in parallel rows thereon, each row of electroluminescent elements comprising an alignment axis, a cover plate adjacent to and spaced apart from the backplane substrate, the cover plate comprising a contrast enhancement layer comprising a base substrate and a filter layer disposed thereon, the filter layer comprising a first plurality of light absorbing wedge-shaped features arranged in parallel rows in a light-transmissive matrix material, further comprises a second plurality of wedge-shaped features arranged in parallel rows with a second height H2 different than H1, the first plurality of wedge-shaped features and the second plurality of wedge-shaped features disposed in an alternating arrangement, each wedge-shaped feature of the first plurality of wedge-shaped features and each wedge-shaped feature of the second plurality of wedge-shaped features comprising a longitudinal axis, and wherein the longitudinal axes are angularly offset from the alignment axes by an angle in a range from greater than zero to 10 degrees.

The optical display device may further comprise a light absorbing layer disposed between the filter layer and the base substrate.

In some embodiments, a height of the second plurality of wedge-shaped features can be less than a height of the first plurality of wedge-shaped features.

In some embodiments, each wedge-shaped feature of the first plurality of wedge-shaped features can comprise a maximum cross-sectional width W1 and each wedge-shaped feature of the second plurality of wedge-shaped features can comprise a maximum cross-sectional width W2, and an aspect ratio H1/W1 of the first plurality of wedge-shaped features can be different than an aspect ratio H2/W2 of the second plurality of wedge-shaped features.

Additional features and advantages of the embodiments disclosed herein will be set forth in the detailed description that follows, and in part will be clear to those skilled in the art from that description or recognized by practicing the embodiments described herein, including the detailed description which follows, the claims, as well as the appended drawings.

Both the foregoing general description and the following detailed description present embodiments intended to provide an overview or framework for understanding the nature and character of the embodiments disclosed herein. The accompanying drawings are included to provide further understanding and are incorporated into and constitute a part of this specification. The drawings illustrate various embodiments of the disclosure, and together with the description explain the principles and operations thereof.

### BRIEF DESCRIPTION OF THE DRAWINGS

FIG. 1 is a schematic view of a prior art electroluminescent display utilizing a circular polarizer;

FIG. 2 is a schematic view of an exemplary electroluminescent display according to embodiments disclosed herein;

FIG. 3 is a schematic representation of an exemplary method of manufacturing a cover plate according to embodiments disclosed herein;

FIG. 4 is a top view of an exemplary pixel showing angles wedge-shaped features positioned overtop electroluminescent elements;

FIG. 5A is a cross-sectional side view of a portion of the electroluminescent display of FIG. 2 showing elements of a contrast enhancement layer;

FIG. 5B is a close-up cross-sectional view of a wedge-shaped feature depicted in FIG. 5A (without fill, for clarity);

FIG. 6 is a schematic diagram showing light emitted by an electroluminescent element intersecting a wedge-shaped feature, in accordance with embodiments disclosed herein;

FIG. 7 is a cross-sectional side view of an exemplary embodiment of another cover plate disclosed herein;

FIG. 8 is a cross-sectional side view of an exemplary embodiment of still another cover plate disclosed herein;

FIG. 9 is a cross-sectional side view of an exemplary embodiment of another cover plate disclosed herein;

FIG. 7 is a plot of normalized transmittance as a function of emission angle from an electroluminescent element (LED) for a range of wedge-shaped feature height;

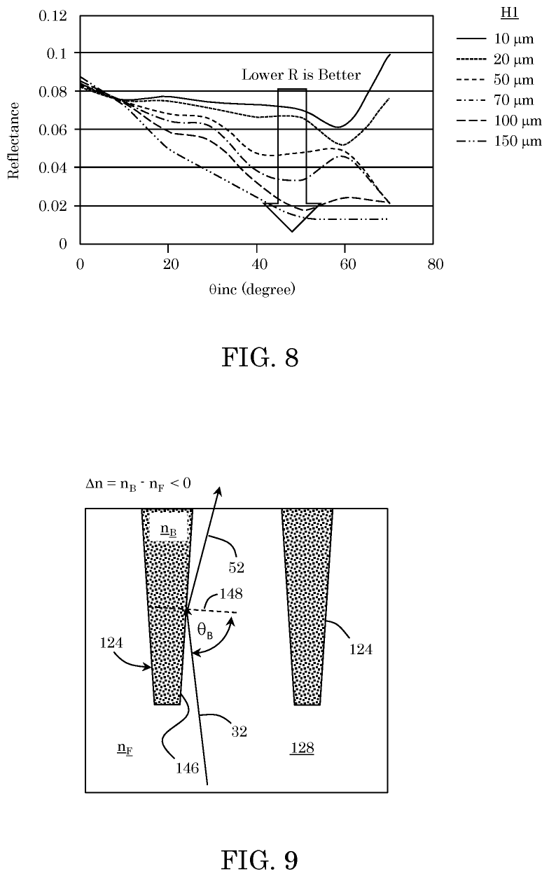

FIG. 8 is a plot of reflectance as a function of incidence angle of ambient light on a display backplane for a range of wedge-shaped feature height;

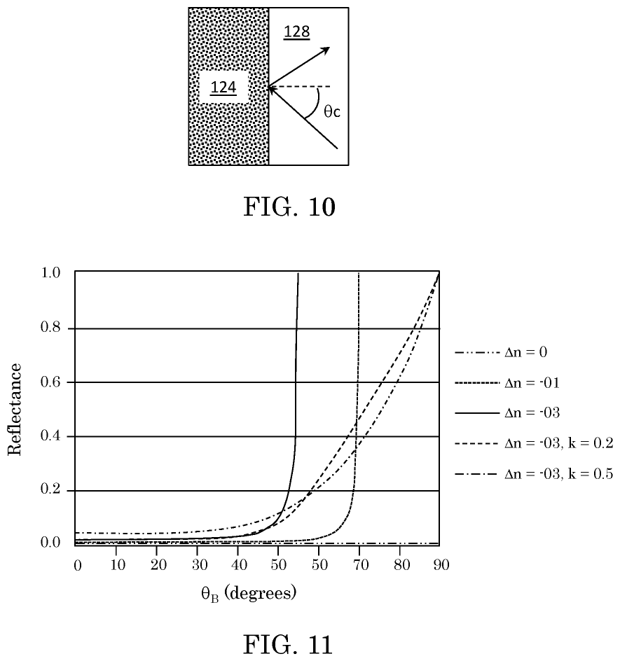

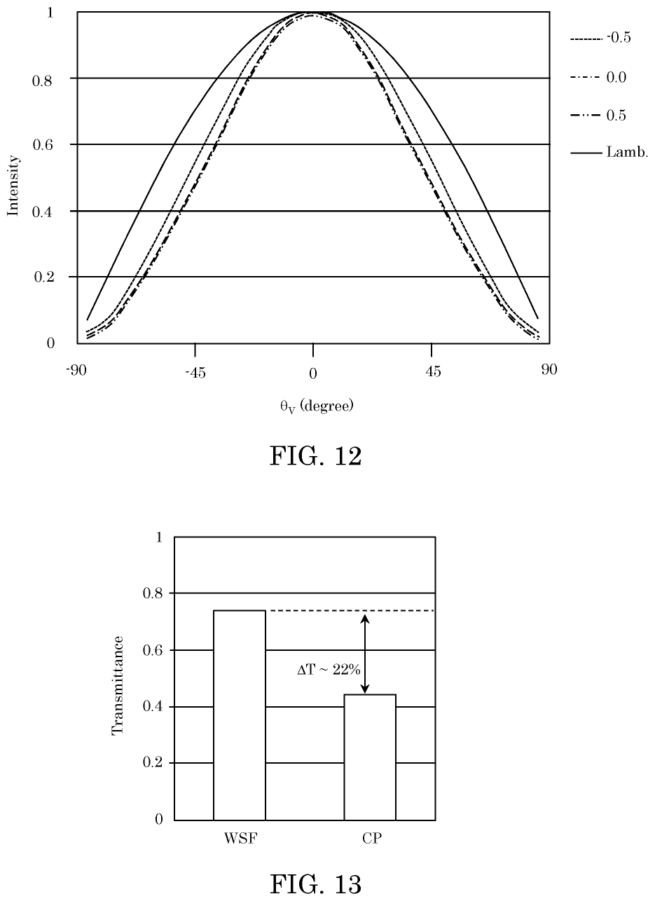

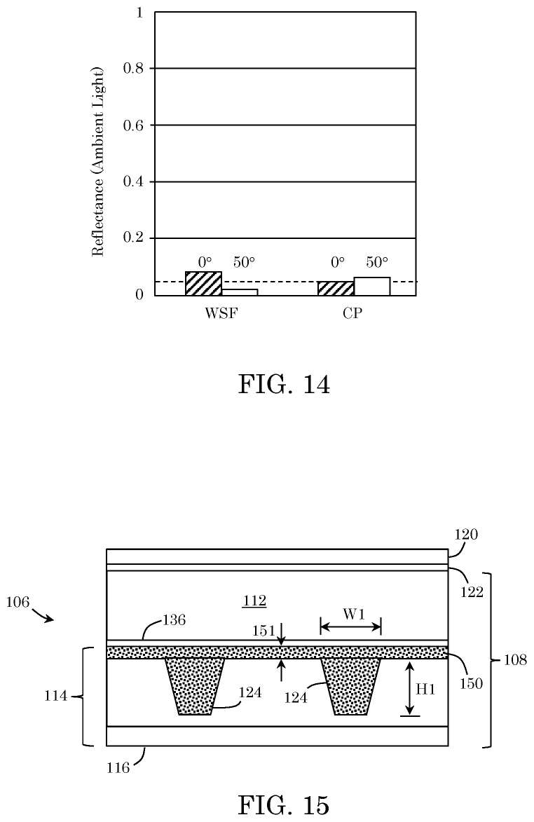

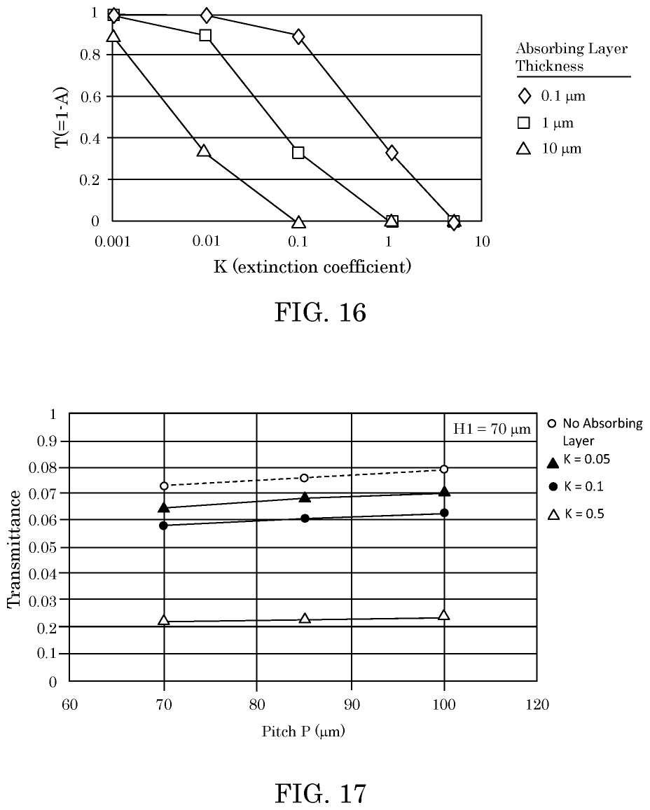

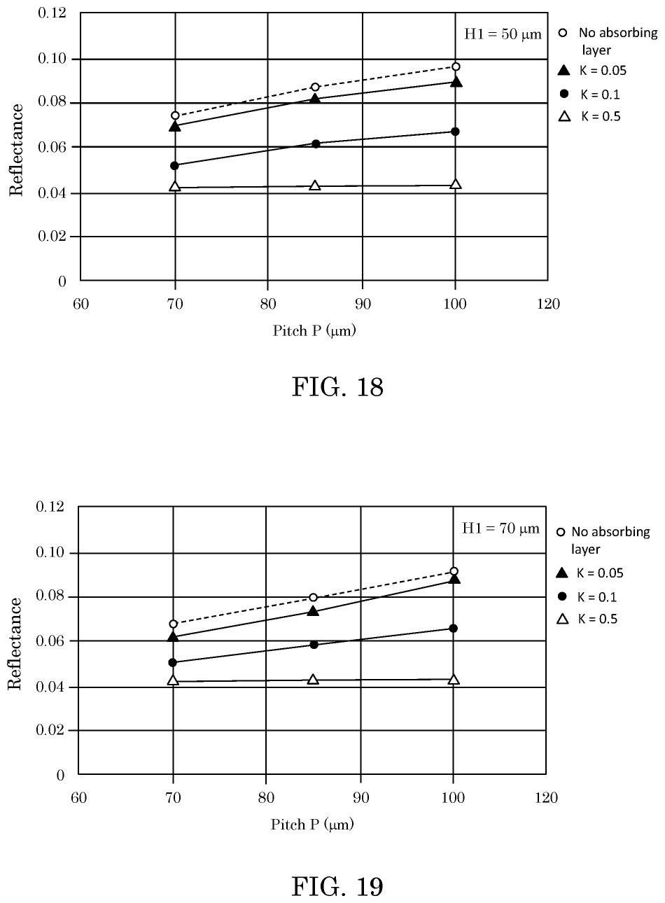

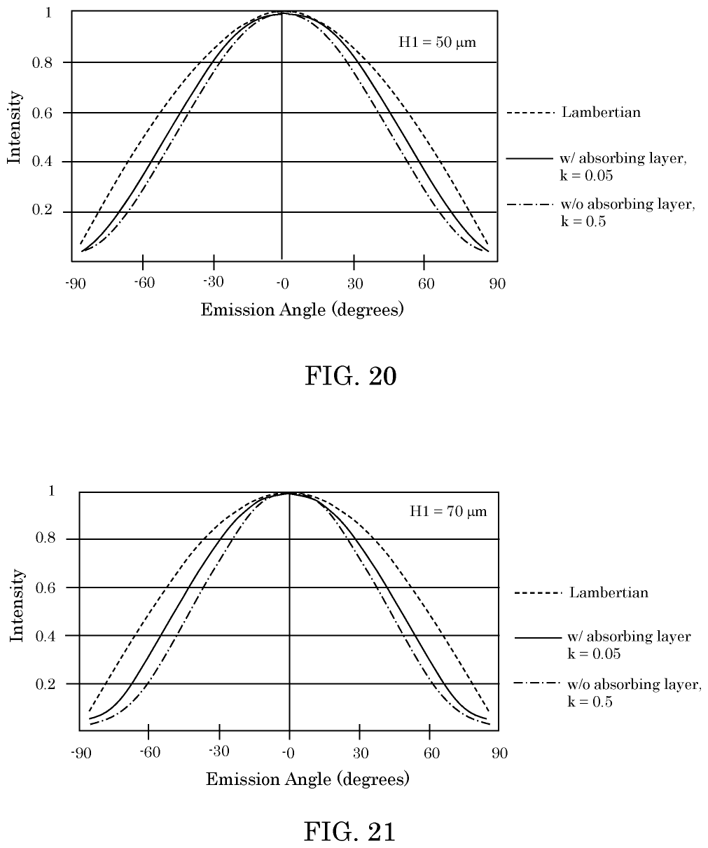

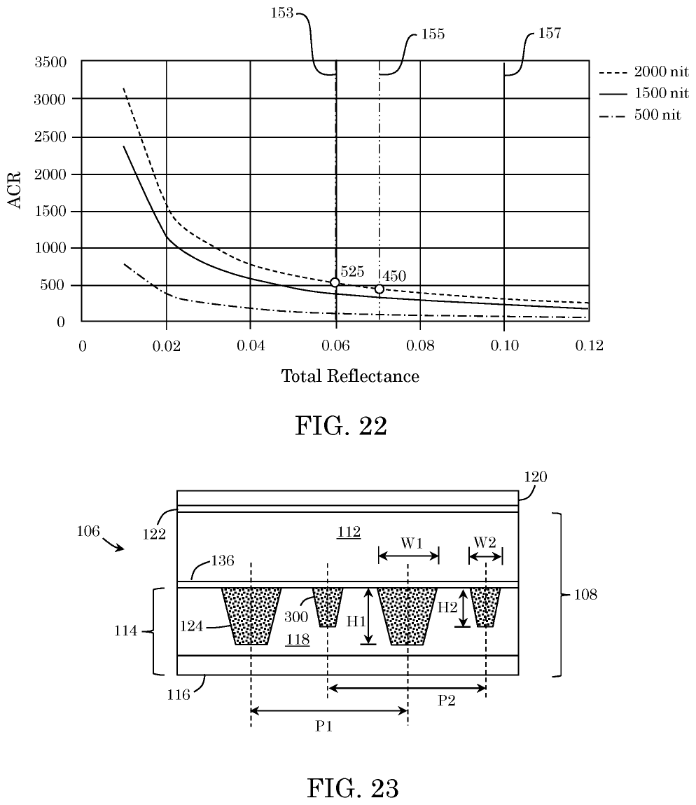

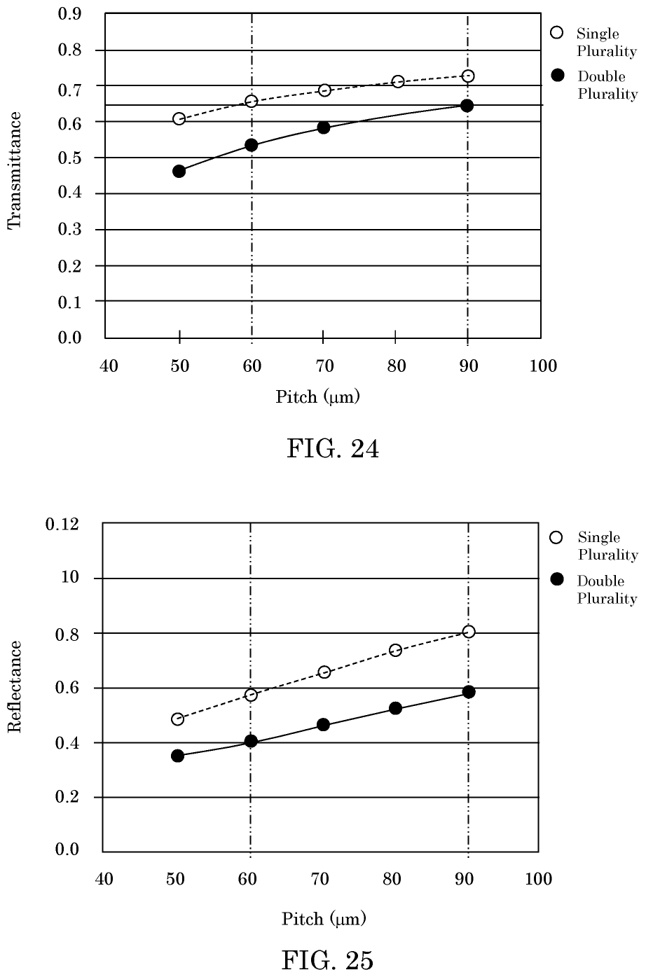

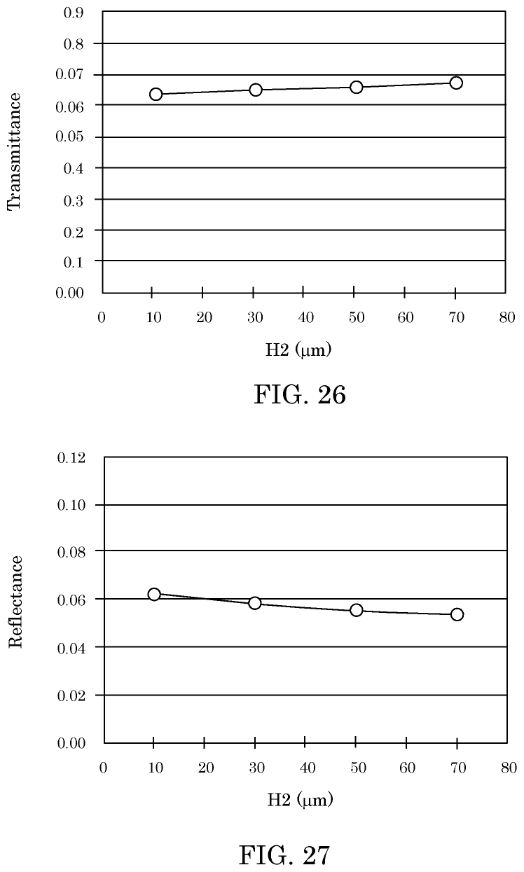

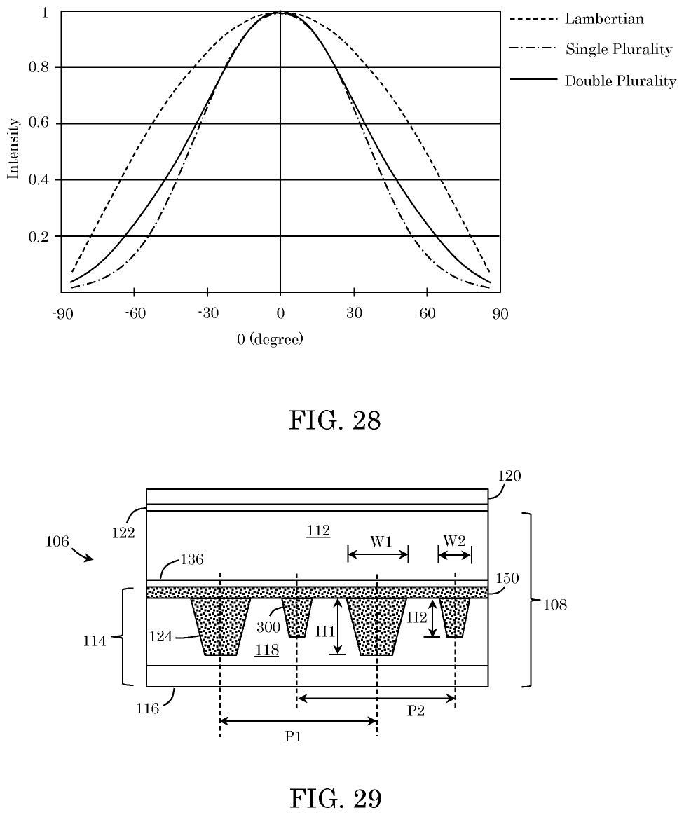

FIG. 9 is a schematic illustration of a light ray emitted from an electroluminescent element incident on and reflected from a wedge-shaped feature;

FIG. 10 is a view of a light ray reflected from a wedge-shaped feature at the critical angle;

FIG. 11 is plot of normalized reflectance as a function of incidence angle on a wedge-shaped feature for a variety of refractive index differences between the wedge-shaped feature and the surrounding matrix material;

FIG. 12 is a plot of normalized intensity as a function of viewing angle θ_{V};

FIG. 13 is a plot showing potential transmittance advantage for a display device utilizing wedge-shaped features (WSF) versus a display device using a circular polarizer (CP);

FIG. 14 is a plot depicting normalized reflectance for a display device comprising wedge-shaped features vs. a circular polarizer for an incoming ambient light ray with an incidence angle of 0° and 50°;

FIG. 15 is a cross-sectional view of another embodiment of a display device cover plate comprising wedge-shaped features and a light absorbing layer;

FIG. 16 is a plot of cover plate transmittance as a function of extension coefficient k;

FIG. 17 is a plot of normalized transmittance as a function of wedge-shaped feature pitch for a variety of values of k and a wedge-shaped feature height H1 of 70 μm;

FIG. 18 is a plot of reflectance as a function of wedge-shaped feature pitch for a variety of values of k and a wedge-shaped feature height H1 of 50 μm;

FIG. 19 is a plot is a plot of reflectance as a function of wedge-shaped feature pitch for a variety of values of k and a wedge-shaped feature height H1 of 70 μm;

FIG. 20 is a plot of normalized intensity as a function of electroluminescent element emission angle comparing a display device with wedge-shaped features with a height of 50 μm and a light absorbing layer and a display device with wedge-shaped features with a height of 50 μm and no light absorbing layer for several values of k;

FIG. 21 is a plot of normalized intensity as a function of electroluminescent element emission angle comparing a display device with wedge-shaped features with a height of 70 μm and a light absorbing layer and a display device with wedge-shaped features with a height of 70 μm and no light absorbing layer for several values of k;

FIG. 22 is a plot of ambient contrast ratio as a function of reflectance presenting a prediction of ambient contrast ratio (ACR) under different levels of ambient illumination and the achievable ACR;

FIG. 23 is a cross-sectional view of another embodiment of a display device cover plate comprising a first plurality of wedge-shaped features with a first aspect ratio and a second plurality of wedge-shaped features with a second aspect ratio;

FIG. 24 is a plot comparing normalized transmittance as a function of pitch for a display cover plate with a first plurality of wedge-shaped features, and a display device with a first plurality of wedge-shaped features with a first aspect ratio and a second plurality of wedge-shaped features with a different aspect ratio;

FIG. 25 is another plot comparing reflectance as a function of pitch for a display cover plate with a first plurality of wedge-shaped features, and a display device with a first plurality of wedge-shaped features with a first aspect ratio and a second plurality of wedge-shaped features with a different aspect ratio;

FIG. 26 is a plot of transmittance as a function of height H2 of a second plurality of wedge-shaped features for a display cover plate with a first plurality of wedge-shaped features with a first aspect ratio and a second plurality of wedge-shaped features with a different aspect ratio;

FIG. 27 is a plot of reflectance as a function of height H2 of a second plurality of wedge-shaped features for a display cover plate with a first plurality of wedge-shaped features with a first aspect ratio and a second plurality of wedge-shaped features with a different aspect ratio;

FIG. 28 is a plot comparing normalized intensity as a function of electroluminescent element emission angle for a display cover plate with a first plurality of wedge-shaped features, and a display device with a first plurality of wedge-shaped features with a first aspect ratio and a second plurality of wedge-shaped features with a different aspect ratio;

FIG. 29 is a cross-sectional view of another embodiment of a display device cover plate comprising a first plurality of wedge-shaped features with a first aspect ratio and a second plurality of wedge-shaped features with a second aspect ratio, and a light absorbing layer.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure can be embodied in many different forms and should not be construed as limited to the embodiments set forth herein.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

Ranges can be expressed herein as from “about” one particular value, and/or to “about” another particular value. When such a range is expressed, another embodiment includes from the one particular value to the other particular value. Similarly, when values are expressed as approximations by use of the antecedent “about,” it will be understood that the particular value forms another embodiment. It will be further understood that the endpoints of each of the ranges are significant both in relation to the other endpoint, and independently of the other endpoint.

Directional terms as used herein—for example, up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural references unless the context clearly dictates otherwise. Thus, for example, reference to “a” component includes aspects having two or more such components, unless the context clearly indicates otherwise.

The word “exemplary,” “example,” or various forms thereof are used herein to mean serving as an example, instance, or illustration. Any aspect or design described herein as “exemplary” or as an “example” should not be construed as preferred or advantageous over other aspects or designs. Furthermore, examples are provided solely for purposes of clarity and understanding and are not meant to limit or restrict the disclosed subject matter or relevant portions of this disclosure in any manner. It can be appreciated that a myriad of additional or alternate examples of varying scope could have been presented but have been omitted for purposes of brevity.

As used herein, the terms “comprising” and “including,” and variations thereof, shall be construed as synonymous and open-ended, unless otherwise indicated. A list of elements following the transitional phrases comprising or including is a non-exclusive list, such that elements in addition to those specifically recited in the list may also be present.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

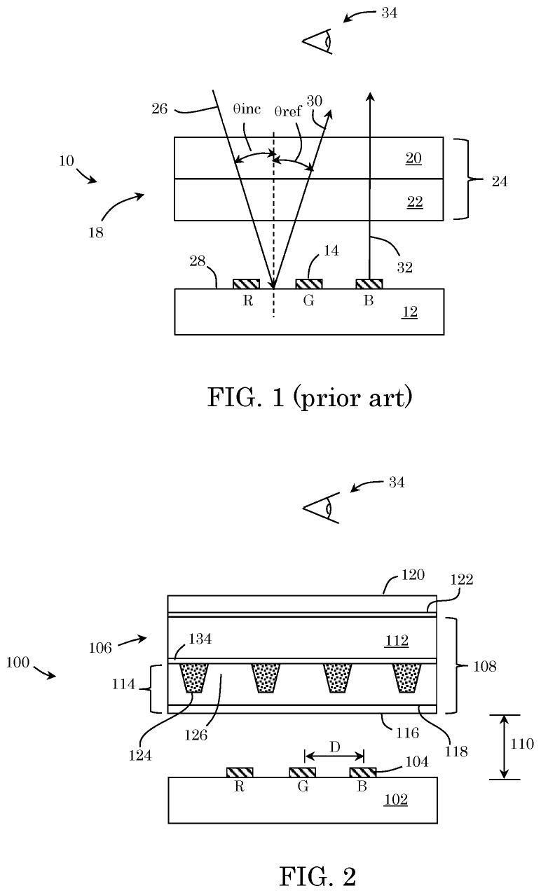

Electroluminescent displays can suffer from surface reflection that can lead to ambient contrast degradation. For example, FIG. 1 depicts a cross-sectional image showing a portion of a conventional micro-LED display 10 comprising a backplane substrate 12 comprising a plurality of electroluminescent elements 14, e.g., LEDs, deposited thereon. The electroluminescent display 10 further comprises a cover plate 18. Cover plate 18 can include a phase retarding layer 20 and a linear polarizing layer 22, which together form circular polarizer 24. As shown in FIG. 1, ambient light rays 26 can enter display 10 through cover plate 18, be incident on first surface 28 of backplane substrate 12 at an incidence angle θ_{inc} relative to a normal to first surface 28 and be reflected from backplane substrate 12. The light ray 30 represents ambient light reflected at reflection angle EU. The plurality of electroluminescent elements 14 can also generate and emit light rays 32. The emitted light 32 can be transmitted through the cover plate 18 in a direction toward external viewer 34 as an image. The reflected ambient light 30 competes with the emitted light 32, which can result in the displayed image having reduced contrast as viewed by viewer 34. As such, display 10, or a portion thereof, can appear to be washed-out to the viewer.

To avoid ambient contrast degradation, a contrast-enhancing cover plate is provided for electroluminescent display applications including light emitting diode (LED) displays, organic light emitting diode (OLED) displays, or quantum dot displays, but which cover plate is particularly useful for micro-LED displays. In some embodiments, the cover plate can comprise a micro-replicated contrast enhancement filter configured to repress reflected ambient light from competing with light emitted by the electroluminescent elements. In some embodiments, the electroluminescent display can have pixel sizes on the order of a few tens of micrometers to hundreds of micrometers. For example, an electroluminescent display may comprise red (R), green (G) and blue (B) LEDs, with each set of red, green, and blue LEDs forming a pixel. In some embodiments, for example, a size of a micro-LED (e.g., a dimension along one side of the LED) can range from about 10 μm to about 1000 μm. In some embodiments, LED chips can be sized with an area in a range of about 10 μm² to about 1000 μm². In such embodiments, the size of the light emitting area of each LED chip can be less than about 20% of the pixel area.

In some embodiments, the cover plate can comprise elements for reducing or eliminating ambient light reflection from the pixels or components thereof. In some embodiments, the elements can comprise a plurality of light absorbing wedge-shaped features, e.g., trapezoidal-shaped features, arranged in rows. The wedge-shaped features can be numerically evaluated and optimized to reduce or eliminate ambient light reflected by the pixel electroluminescent elements (e.g., individual LEDs).

FIG. 2 is a cross-sectional view of an exemplary electroluminescent display device 100 according to the present disclosure comprising a backplane substrate 102 including a plurality of electro luminescent elements 104 deposited thereon and a cover plate 106 including a contrast enhancement layer 108. Electroluminescent elements 104, may comprise individual pixels elements of an image pixel, and may, accordingly, be configured to display different colors, for example red (R), green (G), and/or blue (B). In some embodiments, cover plate 106 can be spaced apart from backplane substrate 102 by an air gap 110. For example, air gap 110 can be in a range from about 50 μm to about 5 mm, for example in a range from about 100 μm to about 5 mm, such as in a range from about 200 μm to about 4 mm, in a range from about 300 μm to about 3 mm, or in a range from about 1 mm to about 3 mm, including all ranges and subranges therebetween.

Contrast enhancement layer 108 can include a base layer 112 and a filter layer 114. In some embodiments, base layer 112 can comprise a glass material, for example a silicate glass material, such as an aluminosilicate glass material. In other embodiments, base layer 112 can comprise a polymer material. Filter layer 114, in turn, may comprise a support layer 116 and a light modifying layer 118.

Cover plate 106 may further comprise an anti-reflection layer 120. Contrast enhancement layer 108 may be joined to antireflection layer 120 by an adhesive layer 122. Adhesive layer 122 may, in some embodiments, comprise a pressure-sensitive adhesive.

Light modification layer 118 comprises a first plurality of light absorbing wedge-shaped features 124 separated by light transmissive regions 126. The first plurality of light absorbing wedge-shaped features 124 can comprise any suitable material that can absorb or block light at least in a portion of the visible spectrum. In some embodiments, the light absorbing materials can include a black colorant, e.g., a black particulate such as carbon black. The carbon black can comprise a particle size equal to or less than about 10 μm, for example equal to or less than about 5 μm, such as equal to or less than 1 μm, equal to or less than about 500 nm, equal to or less than about 300 nm, or equal to or less than about 200 nm, including all ranges and subranges therebetween. In some embodiments, the carbon black can have a mean particle size equal to or less than about 1 μm. In some embodiments, the light absorbing materials can include a colorant having other colors such as white, red, green, or yellow. In further embodiments, the absorbing material, (e.g., carbon black, a pigment or dye, or combinations thereof) can be dispersed in a suitable matrix material.

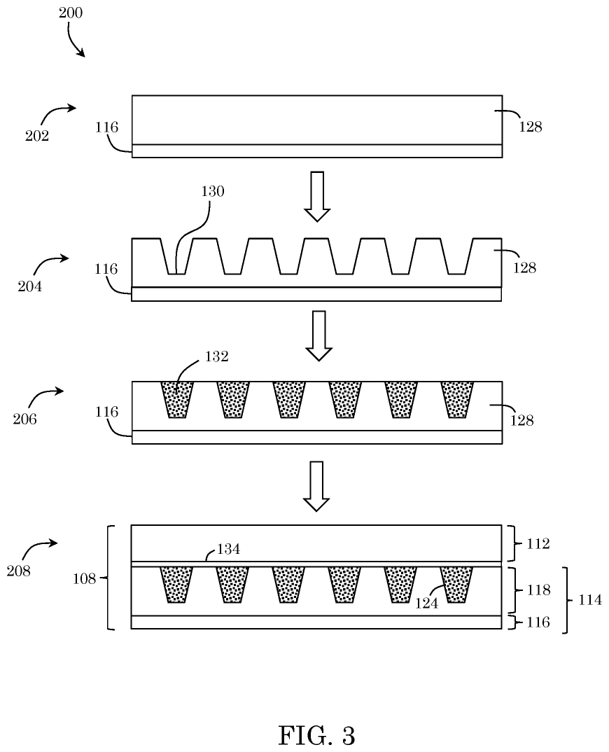

Referring to FIG. 3, an exemplary process 200 for forming cover plate 106 is shown. In a first step, 202, a suitable matrix material 128 (e.g., an acrylate resin and bisphenol fluorine diacrylate) can be deposited on support layer 116 (e.g., a layer of polyethylene terephthalate (PET)). The matrix material 128 can be patterned at step 204, for example by using a patterned roller, to produce wedge-shaped recesses 130. Patterning can be performed, for example, in a roll-to-roll process. The matrix material can be cured, wholly or partially, and then be filled with a light absorbing material 132 at step 206. The light absorbing material is cured and can then be applied to a surface of base layer 112 as shown in step 208, such as with an adhesive layer 134 (e.g., a pressure sensitive adhesive) to form contrast enhancement layer 108.

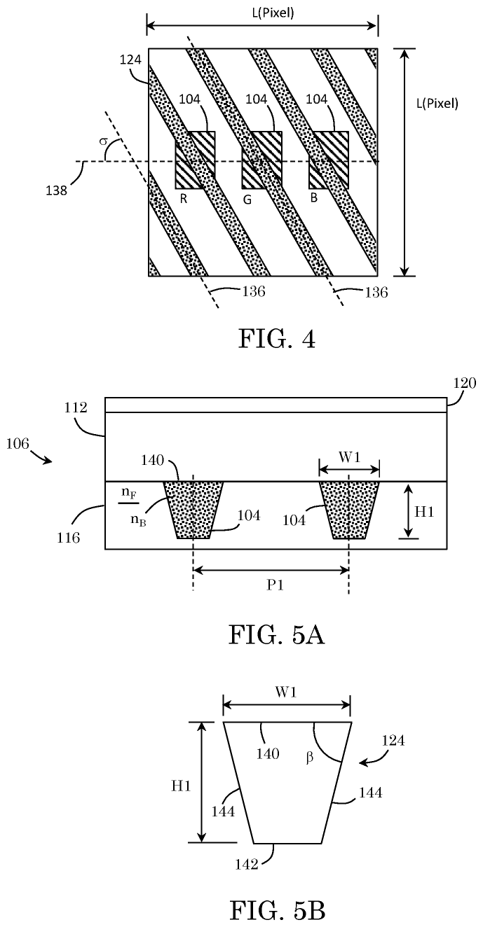

FIG. 4 is a top view of a portion (e.g., a single pixel) of an electroluminescent display viewed from the viewer side of the display showing rows of a first plurality of elongate wedge-shaped features 124 arranged in parallel rows, each wedge-shaped feature of the first plurality of wedge-shaped features comprising a longitudinal axis 136. As shown, the wedge-shaped features are located between the electroluminescent elements and the viewer. As further shown, the first plurality of wedge-shaped features 124 may not be aligned with an alignment axis 138 of a row of electroluminescent elements 104, but instead can be angled across the electroluminescent elements by an angle σ. Angle σ can be in a range from about 0 to about 10 degrees, for example in a range from greater than κ degrees to about 10 degrees.

Conditions for a design of filter layer 114 can be identified by parametric studies on structural variations and the refractive index of the wedge-shaped features. For example, in some embodiments, a maximum width W1 of individual wedge-shaped features of the first plurality of wedge-shaped features, taken at a base 140 of the wedge-shaped features, can be less than one half the length L(pixel) of a display pixel (L(pixel)/2) for a transmittance T greater than 50%. Transmittance is the ratio of transmitted light power through a given geometry to injected light power along the normal direction. For example, in some embodiments, the wedge-shaped feature maximum width W1 can be in a range from about 10 μm to about 100 μm. For example, for some specific backplane substrate designs (e.g., LED chip size: 38×54 μm², L(pixel)=432 μm, D(chip-to-chip)=100 μm), W1 can be in a range from about 20 μm to about 25 μm. In some embodiments, L(pixel) can be in a range from about 10 μm to about 1000 μm.

FIGS. 5A and 5B illustrate a portion of contrast enhancement layer 108 showing dimensional parameters of wedge-shaped features 124. In some embodiments, each wedge-shaped feature 124 of the first plurality of wedge-shaped features can comprise a maximum width W1 taken at base 140 of the feature (see FIG. 5B, fill omitted for clarity), a height H1 taken from base 140 to the opposing end 142 of the wedge-shaped feature, a pitch P1 taken as the distance from the center of one wedge-shaped feature 124 to the center of an immediately-adjacent wedge-shaped feature 124, and a wedge angle β evaluated between base 140 of a wedge-shaped feature 124 and an adjacent side 144 of the wedge-shaped feature.

In some embodiments, wedge angle β can be in a range from about 70 degrees to less than 90 degrees. As such, maximum width W1 at base 140 is greater than the narrower width at opposing end 142. In other words, the wedge-shaped feature can comprise a trapezoidal cross-sectional shape with base 140 and opposing side 142 projecting from base 140 toward the plurality of electroluminescent elements 104. This arrangement can improve ambient light reduction while simultaneously providing a larger viewing angle for the electroluminescent display. The viewing angle is an angle at which the brightness of the electroluminescent display to a viewer is one half the brightness evaluated along a normal to the electro luminescent display (e.g., a normal to the cover plate).

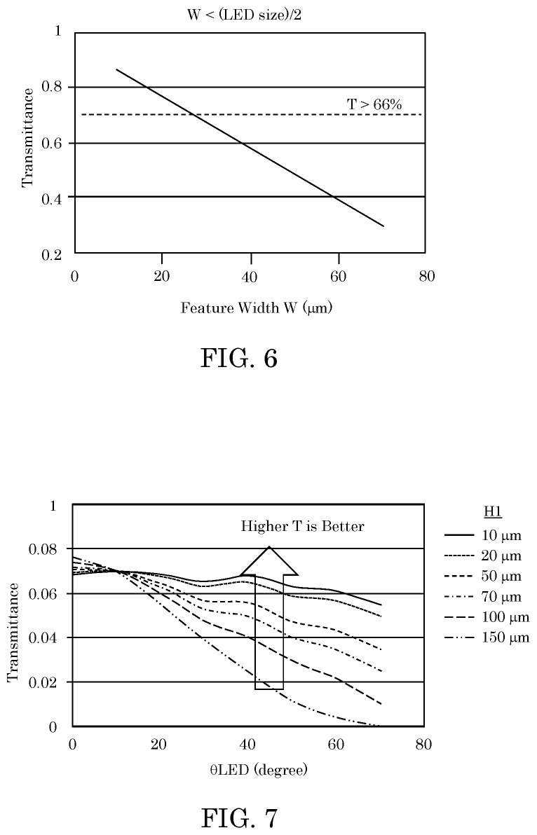

FIG. 6 is a graph showing modeled cover plate transmittance as a function of feature width W1. The data show that as wedge-shaped feature width W1 decreases, transmittance increases. For a transmittance greater than about 66%, a wedge-shaped feature width can be about 25 μm, although other widths are possible depending on desired transmittance.

FIGS. 7 and 8 show, respectively, transmittance and reflectance for varying wedge-shaped feature heights H1 as a function of LED emission angle (FIG. 7) and angle of incidence (FIG. 8). The data shown in FIG. 7 show that as wedge-shaped feature height H1 decreases, transmittance desirably increases. Conversely, the data shown in FIG. 8 indicate that as wedge-shaped feature height H1 decreases, reflectance undesirably increases. As the emission angle of an electroluminescent element increases, transmittance decreases. As the angle of incidence of the ambient light increases, reflectance decreases until an angle of incidence of about 60° is reached, then there is divergent behavior between large height (greater than about 50 μm) and small heights, less than about 50 μm, e.g., 20 μm). For heights H1 of 20 μm and 10 μm and an angle of incidence greater than about 60°, reflectance increases, but decreases for heights of 50 μm-150 μm. Thus, wedge-shaped feature height can involve a trade-off between transmittance and reflectance to find an optimum height H1 for a particular device configuration.

In various embodiments, height H1 can be in a range from about 50 μm to about 100 μm. Accordingly, in some embodiments, a height-to-width aspect ratio H1/W1 of a wedge-shaped feature 124 can be equal to or greater than about 2, for example equal to or greater than about 3. In some embodiments, for example, the aspect ratio H1/W1 can be in a range from about 3 to about 6, or from about 3 to about 5, or less than about 5, or less than about 4.

In some embodiments, pitch P1 of the wedge-shaped features 124 can be less than or equal to D (chip-to-chip). For example, pitch P1 can be in a range from about 40 μm to about 500 μm, for example from about 50 μm to about 200 μm, such as in a range from about 60 μm to about 150 μm, from about 60 μm to about 100 μm, or in a range from about 60 μm to about 90 μm, including all ranges and subranges therebetween.

Additionally, each wedge-shaped feature 124 can comprise an index of refraction n_{B}, and matrix material 128 can comprise an index of refraction n_{F}. In some embodiments, the refractive index n_{B} of the wedge-shaped features 124 can be selected to improve the viewing angle of the display. For example, FIG. 9 is a schematic diagram showing two adjacent wedge-shaped features (fill omitted for clarity) and a light ray 32 emitted by an electroluminescent element 104 intersecting side surface 146 of a wedge-shaped feature 124 at an angle θ_{B} relative to a normal 148 to the intersected surface. FIG. 10 is a close-up view illustrating when θ_{B} is equal to or greater than θ_{c}, the critical angle at which total reflection occurs (θ_{C}=arcsin n_{B}/n_{F}). A difference Δn between the index of refraction of the wedge-shaped feature 124, n_{B}, and the refractive index of the surrounding matrix material 128, n_{F}, i.e., Δn=n_{B}−n_{F}, can create large reflectance values at high incidence angles due to total internal reflection, e.g., θ_{B}>θ_{C}, as shown in the modeled data of FIG. 11. FIG. 12 is a plot of modeled and normalized light intensity as a function of viewing angle (θ_{V}) for several values of Δn and compared to a Lambertian distribution. The arrangement of the plurality of wedge-shaped features 124 into parallel rows, the wedge angle β between the base of a wedge-shaped feature and an adjacent side of the wedge-shaped feature, the height to width (H/W) aspect ratio, and the trapezoidal cross-sectional shape having a base and an opposing top projecting toward the plurality of electroluminescent elements, all contribute to the improvements observed in transmittance and viewing angle. The data show viewing angle can be improved (increased) by selecting a material for the wedge-shaped features with an index of refraction n_{B} less than the index of refraction n_{F} for the matrix material surrounding the wedge-shaped feature. For example, the viewing angle may be improved to greater than 30 degrees, or greater than 40 degrees, or greater than 45 degrees. In various embodiments, matrix material 128 and/or light absorbing material 132 can be selected to provide a Δn in a range from about −0.5 to about 0, for example in a range from about −0.3 to 0.

FIGS. 13 and 14 show, respectively, modeled transmittance and reflectance between a cover plate comprising wedge-shaped features (WSF) 124 and a display device comprising a conventional circular polarizer (CP). The data in FIG. 13 predict an approximately 22% increase in transmittance for the cover plate using wedge-shaped features as described herein. FIG. 14 shows that, for an incoming ambient light ray with an incidence angle of 0° and 50°, while the amount of ambient reflected light can be greater for the wedge-shaped feature display, the circular polarizer-equipped display demonstrates a significant increase in reflected light at an incidence angle θ_{inc} of 50° compared to the WSF display at the same incidence angle. The improved optical transmittance of the WSF cover plate can utilize a lower injection of electrical current into the electroluminescent elements (e.g., micro-LEDs) to obtain the same brightness as the circularly polarizing cover substrate. This provides additional benefits for the display device (e.g., micro-LED display), including, for example, longer display lifetime and reliability. In some embodiments, the optical transmittance of an WSF cover plate can be at least 50%, for example at least 60%, at least 70%, at least 80%, or at least 90%.

Turning now to FIG. 15, in still other embodiments, filter layer 114 may comprise an optional absorbing layer 150 positioned between light modifying layer 118 and base layer 112. Light absorbing layer 150 can be formed from the same or similar material as wedge-shaped features 124. Accordingly, in various embodiments, a transmittance of light absorbing layer 150 can be controlled by controlling a density of light absorbing material 132 disposed in light absorbing layer 150 and/or a thickness 151 of light absorbing layer 150 to obtain a predetermined transmittance. For example, light absorbing layer 150 can contain carbon particles (e.g., carbon black) or other suitable particles with a density in a range from about 1% by weight to about 20% by weight, for example in a range from about 5% by weight to 15% by weight. A thickness of light absorbing layer 150 can be in a range from about 10 nm to about 1 micrometer. As described in more detail below, in some embodiments, density and/or thickness can be used to obtain a transmittance of at least about 60%. While light absorbing layer 150 can result in a small transmittance reduction for cover plate 106 compared to a cover plate with wedge-shaped features 124 but no light absorbing layer 150, the result can be an increased contrast ratio. For example, in some embodiments, a contrast ratio equal to or greater than about 500 can be attained by including both wedge-shaped features 124 and light absorbing layer 150.

An extinction coefficient k of light absorbing layer 150 can be selected to match a target transmittance, for example, a transmittance equal to or greater than 60%. The extinction coefficient k is the imaginary component of the complex refractive index (n+ik) and can be varied by selecting particle density and or thickness of light absorbing layer 150, which can determine absorption level. The extinction coefficient k can be calculated from the following equation, T=e\hat{ }(4nk/λ)d, where T represents transmittance, d represents the thickness of the film, and n is refractive index (\hat{ } indicates exponent). FIG. 16 shows a theoretical prediction of optical transmittance (or absorption) of a thin absorbing layer 150 for layer thicknesses d (from 0.1 μm to 10 μm), and its extinction coefficient, k, as a function of transmittance T (equal to 1-absorbance, A).

The performance impact of a light absorbing layer 150 was numerically evaluated by ray-optic simulation, results of which analysis are shown in FIGS. 17-19. The pitch P1 (spatial period) of wedge-shaped features 124 was one of the geometric parameters studied, together with k. For this analysis, it was assumed reflectance at backplane substrate 102 was 10% of the incident ambient light. The target transmittance and reflectance of the cover plate was 60% and 70%, respectively. FIG. 17 is a plot of transmittance as a function of pitch P1 for various values of k and a wedge-shaped feature height H1 of 70 μm. The data show that as k increases (light absorbing layer 150 becomes more absorptive), for example greater than 0.05, transmittance decreases accordingly (Since reflectance is inversely proportional to ambient contrast ratio (ACR), optical transmittance and ACR are in an opposing relationship). ACR is calculated as 1+Iₒ/(I_{amb}−R_{amb}), where Iₒ is an intensity of light emitted by the electroluminescent element in an “on” state, I_{amb} is the intensity of the ambient light, and R_{amb} is the reflectance of the ambient light. To satisfy both transmittance and reflectance needs, k can be selected to be in a range from about 0.05 to about 1 as indicated by FIG. 17. The choice of k can also depend on the thickness of light absorbing layer 150. For example, the thickness 151 of light absorbing layer 150 can be in a range from about 0.1 μm to about 10 μm.

In addition, the height H1 of wedge-shaped features 124 was evaluated over a range from about 50 μm to about 70 μm. FIG. 18 is a graph of modeled reflectance as a function of pitch for various values of k and a wedge-shaped feature height H1 of 50 μm, and FIG. 19 is a graph of modeled reflectance as a function of pitch for various values of k and a wedge-shaped feature height H1 of 70 μm. The data show that as k increases, reflectance decreases, but conversely, as pitch increases reflectance increases. Testing has shown that reducing the height H1 of the wedge-shaped features can make both patterning of recesses 130 and processes for filling those recesses with light absorbing material 132 more reliable. These behaviors can be used to find an appropriate trade-off between pitch, wedge-shaped feature height, and k that minimizes reflectance. Interestingly, the data for a large value of k, in both simulations, i.e., k=0.5, shows a low reflectance sensitivity for both pitch and height, a trend evident in the lesser values of k. That is, the data show that at high values of k, reflectance varies little as a consequence of changes in wedge-shaped feature pitch and height.

Angular emission profiles of LED light emitted from a display (e.g., from cover plate 106) in the presence of light absorbing layer 150 was also analyzed, since the emission profile can help determine electroluminescent display viewing angle. The cases of H1=50 μm (FIG. 20) and 70 μm (FIGS. 20 and 21) were again evaluated and compared to a cover plate without light absorbing layer 150. FIGS. 20 and 21 present modeled and normalized intensity as a function of electroluminescent element emission angle. This analysis confirmed the presence of light absorbing layer 150 in addition to wedge-shaped features 124 can provide increased viewing angle compared to cover plates without light absorbing layer 150. The data show that a cover plate comprising both wedge-shaped features 124 and light absorbing layer 150, exhibiting an extinction ratio in a range from about 0.01 to about 0.1, can provide an ACR in excess of 500 in micro-LED displays.

FIG. 22 is a graph showing modeled ambient contrast ratio as a function of total reflectance. The data present a prediction of ambient contrast ratio (ACR) under different levels of ambient illumination and the achievable ACR. For example, axis 153 represents a display device comprising a plurality of wedge-shaped features and a light absorbing layer 150 as disclosed herein, whereas axis 155 represents the same display with wedge-shaped features 124 but without light absorbing layer 150. As a comparison, axis 157 represents the same display without wedge-shaped features 124 and without light absorbing layer 150. The amount of ambient light reflectance from the backplane was assumed to be 10%. The data show that an ACR greater than 500 is achievable by a display device with both light absorbing wedge-shaped features 124 combined with light absorbing layer 150 positioned between the wedge-shaped features and the base layer.

Shown in FIG. 23 is still another embodiment of cover plate 106, wherein the cover plate can comprise alternating rows of wedge-shaped features of differing heights and differing widths. FIG. 23 depicts a cross-sectional view of a portion of cover plate 106 comprising base layer 112 and light modifying layer 118 comprising a plurality of wedge-shaped features embedded therein. The plurality of wedge-shaped features can include a first plurality of wedge-shaped features 124 comprising the same attributes as previously described, and a second plurality of wedge-shaped features 300. The first plurality of wedge-shaped features 124 can be arranged as rows of elongate wedge-shaped features with maximum width W1 and a height H1 as previously described. The second plurality of wedge-shaped features 300 can also be arranged as parallel rows of elongate wedge-shaped features with a maximum width W2 at the base of the wedge-shaped features 300 and a height H2, where the height H2 is evaluated from the base of wedge-shaped features 300 to the opposing end (the end farthest from base layer 112) in the same manner as wedge-shaped features 124. The second plurality of wedge-shaped features can be arranged in an alternating arrangement with the first plurality of wedge-shaped features. In some embodiments, height H2 of wedge-shaped features 300 of the second plurality of wedge-shaped features can be less than the height H1 of wedge-shaped features 124 of the first plurality of wedge-shaped features. In some embodiments, maximum width W2 of wedge-shaped features 300 of the second plurality of wedge-shaped features can be less than the maximum width W1 of wedge-shaped features 124 of the first plurality of wedge-shaped features. Accordingly, in some embodiments, both height H2 and maximum width W2 can be less than the height H1 and the maximum width W1 of wedge-shaped features 124 of the first plurality of wedge-shaped features. In some embodiments, an aspect ratio H1/W1 can be equal to or greater than about 3, for example, in a range from about 3 to about 6.

Referring still to FIG. 23, wedge-shaped features 124 can be periodically spaced with a pitch P1 defining a separation distance between the adjacent wedge-shaped features as measured from a center one of wedge-shaped feature 124 to the center of the adjacent wedge-shaped feature 124. In various embodiments, pitch P1 of the first plurality of wedge-shaped features can be in a range from about 50 μm to about 200 μm, for example in a range from about 60 μm to about 150 μm, from about 60 μm to about 100 μm, or in a range from about 60 μm to about 90 μm. Additionally, wedge-shaped features 300 may also be periodically spaced, with a pitch P2 defining a separation distance between adjacent wedge-shaped features 300 as measured from a center of one wedge-shaped feature 300 to the center of another, adjacent, wedge-shaped feature 300. In various embodiments, each wedge-shaped feature 300 can be positioned half way between adjacent wedge-shaped features 124 such that P2 is equal to P1. That is, the second plurality of wedge-shaped features can be equally spaced between the first plurality of wedge-shaped features. Thus, a distance between the center of a wedge-shaped feature 124 and an adjacent wedge-shaped feature 300 can be (P1)/2.

FIGS. 24 and 25 present modeled data showing transmittance (FIG. 24) and reflectance (FIG. 25) as a function of pitch P1 and assuming P2=P1. The data show a comparison of a display with a single plurality of wedge-shaped features vs. a display with two pluralities of wedge-shaped features, wherein a height of the second plurality of wedge-shaped features is different than a height of the first plurality of wedge-shaped features. The data further show that a display with two pluralities of wedge-shaped features with a larger pitch P1 (e.g., 90 μm) can have similar optical performance as a display with a single plurality of wedge-shaped features of the same height and a short pitch (e.g., 60 μm) while satisfying a desire to maintain a transmittance over 60% and reflectance below 8%. Although the addition of the second plurality of wedge-shaped features can make the overall pattern of wedge-shaped features denser when viewed from a viewer's perspective, the additional plurality of wedge-shaped features with a low aspect ratio does not deteriorate viewing angle for a human observer and can provide an absorptive geometry that helps ambient light rejection.

FIGS. 26 and 27 present modeled data for a display having two pluralities of wedge-shaped features and show transmittance (FIG. 25) and reflectance (FIG. 26) as a function of height H2. With H2 ranging from 10 μm to 70 μm, the result is different from the trend observed with pitch variation. However, the impact of H2 is not so considerable, giving a change in transmittance less than 10% and a change in reflectance less than 1% under the assumption that the absorbing material is highly absorption, e.g. extinction coefficient k is greater than 0.1.

The data show that a greater height H2 gives rise to greater transmittance and a lower reflectance. Transmittance increases according to a greater height H2 because surface area inducing total internal reflection widens. However, reflectance decreases due to an increased aspect ratio of the second plurality of wedge-shaped features.

FIG. 28 is a plot of modeled angular emission profiles for light emitted from an electroluminescent element with a single (first) plurality of wedge-shaped features and a display with two (first and second) pluralities of wedge-shaped features. In this comparison, the display with a single plurality of wedge-shaped features and the display with two pluralities of wedge-shaped features have pitches (P1, P2) of 60 μm and 90 μm, respectively. The data show a display with two pluralities of wedge-shaped features with different aspect ratios can have an improved viewing angle compared to a display with a single plurality of wedge-shaped features, without sacrificing basic optical performance.

FIG. 29 illustrates yet another embodiment of a cover plate according to the present disclosure, the cover plate of FIG. 29 includes both first and second pluralities of wedge-shaped features having different heights and maximum widths and a light absorbing layer 150 positioned between the pluralities of wedge-shaped features and base layer 112.

It will be apparent to those skilled in the art that various modifications and variations can be made to embodiments of the present disclosure without departing from the spirit and scope of the disclosure. Thus, it is intended that the present disclosure cover such modifications and variations provided they come within the scope of the appended claims and their equivalents.

What is claimed is:

1. An optical display device, comprising:
a backplane substrate comprising a plurality of electroluminescent elements deposited in parallel rows thereon, each row of electroluminescent elements comprising an alignment axis;
a cover plate adjacent to and spaced apart from the backplane substrate, the cover plate comprising a contrast enhancement layer comprising a base layer and a filter layer disposed thereon, the filter layer comprising a first plurality of light absorbing wedge-shaped features arranged in parallel rows in a light-transmissive matrix material, each wedge-shaped feature comprising a longitudinal axis; and
wherein the longitudinal axes are angularly offset from the alignment axes by an angle in a range from greater than zero to 10 degrees.

2. The optical display device of claim 1, wherein the cover substrate further comprises a light absorbing layer disposed between the filter layer and the base layer.

3. The optical display device of claim 2, wherein a thickness of the light absorbing layer is in a range from about 10 nm to about 1 μm.

4. The optical display device of claim 1, wherein a height H1 of the first plurality of wedge-shaped features is in a range from about 10 μm to about 100 μm.

5. The optical display device of claim 4, wherein the cover plate further comprises a second plurality of wedge-shaped features with a second height H2 different than H1, the first plurality of wedge-shaped features and the second plurality of wedge-shaped features disposed in an alternating arrangement.

6. The optical display device of claim 4, wherein H1 is in a range from about 50 μm to about 100 μm.

7. The optical display device of claim 5, wherein H2 is in a range from about 5 μm to about 80 μm.

8. The optical display device of claim 5, wherein each wedge-shaped feature of the first plurality of wedge-shaped features comprises a first maximum cross-sectional width W1 and each wedge-shaped feature of the second plurality of wedge-shaped features comprises a second maximum cross-sectional width W2 different than W1.

9. The optical display device of claim 8, wherein W1 is in a range from about 10 μm to about 100 μm.

10. The optical display device of claim 8, wherein W2 is in a range from about 10 μm to about 50 μm.

11. The optical display device of claim 8, wherein H1/W1 is equal to or greater than about 2.

12. (canceled)

13. The optical display device of claim 1, wherein a pitch P1 of the first plurality of wedge-shaped features is in a range from about 20 μm to about 200 μm

14.-16. (canceled)

17. The optical display device of claim 2, wherein an extinction coefficient k of the filter layer is in a range from about 0.01 to about 1.

18. The optical display device of claim 17, wherein k is in a range from about 0.05 to about 1.

19.-22. (canceled)

23. The optical display device of claim 1, wherein the optical display device exhibits a viewing angle greater than 30 degrees.

24. The optical display device of claim 1, wherein a refractive index of the first plurality of wedge-shaped features is n_{B} and refractive index of the matrix material is n_{F}, and Δn=n_{B}−n_{F} is in a range from about −0.3 to about 0.

25. The optical display device of claim 24, wherein Δn is in a range from about −0.1 to about 0.

26.-27. (canceled)

28. The optical display device of claim 1, wherein the base layer comprises glass.

29. The optical display device of claim 1, wherein an ambient contrast ratio of the display device is >400 and a transmittance of the cover plate is greater than about 55%.

30. The optical display device of claim 2, wherein an ambient contrast ratio of the display device is >500 and a transmittance of the cover plate is greater than about 50%.

31.-39. (canceled)
